(19) United States
(12) Patent Application Publication
(10) Pub. No.: US 2009/0110917 A1
(43) Pub. Date: Apr. 30, 2009

(54) Electronic Package and Method of Preparing Same

(76) Inventors: John Albaugh, Freeland, MI (US); Robert Camilletti, Midland, MI (US)

Correspondence Address: DOW CORNING CORPORATION CO1232, 2200 W. SALZBURG ROAD, P.O. BOX 994, MIDLAND, MI, 48686-0994, US

(21) Appl. No.: 12/301,039

(22) PCT Filed: Apr. 24, 2007
(86) PCT No.: PCT/US07/09917

§ 371 Date: Nov. 17, 2008

Related U.S. Application Data
(60) Provisional application No. 60/811,223, filed on Jun. 5, 2006.

(51) Int. Cl. H01L 23/29; B05D 5/00; H01L 23/31; G03F 7/075; B32B 9/04

(52) U.S. Cl. 428/336; 427/58; 428/411.1

(57) ABSTRACT

An electronic package comprising an interfacial coating between a first inorganic barrier coating and a second inorganic barrier coating, wherein the interfacial coating comprises a cured product of a silicone resin; and methods of preparing the electronic package.

### CROSS-REFERENCE TO RELATED APPLICATIONS

This application claims the benefit of U.S. Provisional Patent Application Ser. No. 60/811,223, filed on 5 Jun. 2006, under 35 U.S.C. §119(e). U.S. Provisional Patent Application Ser. No. 60/811,223 is hereby incorporated by reference.

### FIELD OF THE INVENTION

The present invention relates to an electronic package and more particularly to an electronic package comprising an interfacial coating between a first inorganic barrier coating and a second inorganic barrier coating, wherein the interfacial coating comprises a cured product of a silicone resin. The present invention also relates to methods of preparing the electronic package.

### BACKGROUND OF THE INVENTION

Barrier coatings play an important role in a wide range of applications including electronic packaging, food packaging, and surface treatment, by protecting sensitive materials from air, moisture, and environmental contaminants. In particular, barrier coatings are frequently applied to electronic devices to protect sensitive electrical contacts from various gases and liquids in the environment. As a result, such coatings increase the reliability and useful lifespan of many consumer products.

Barrier coatings comprising a single layer of an inorganic material, such as a metal oxide or nitride are known in the art. However, such coatings are often too brittle for use on materials having high thermal expansion, such as polymer substrates. Stresses develop in the barrier layer due to differences in the coefficients of thermal expansion between the substrate and the coating. Thermally induced stresses can cause cracking of the barrier coating, thereby reducing the effectiveness of the coating and reliability of the device.

One approach to reducing crack formation in barrier coatings is to deposit an organic coating adjacent to the barrier coating. These multilayer coatings typically comprise alternating layers of inorganic and polymer materials. For example, International Application Publication No. WO 03/016589 A1 to Czeremuszkin et al. discloses a multilayer structure comprising an organic substrate layer, and a mutilayer permeation barrier thereon, the barrier comprising a) a first inorganic coating contacting a surface of the substrate layer, and b) a first organic coating contacting a surface of the inorganic coating.

International Application Publication No. WO 02/091064 A2 to Ziegler, et al. discloses a method of making a flexible barrier material to prevent the passage of water and oxygen to a device which incorporates organic display material, said method comprising the steps of providing a polymer layer; depositing an inorganic barrier layer on the polymer layer by ion-assisted sputtering or evaporation; and depositing a second polymer layer on said inorganic layer, whereby a composite barrier material is provided that can be associated with an electronic display device to prevent degradation of the properties thereof as a result of passage of water and/or oxygen.

U.S. Patent Application Publication No. US2003/0203210 A1 to Graff et al. discloses a multi-layer barrier coating on a flexible substrate comprising alternating polymer and inorganic layers, wherein the layer immediately adjacent to the flexible substrate and the topmost isolation layer may both be inorganic layers.

European Patent Application Publication No. EP1139453 A2 discloses, inter alia, a self-light emitting device having an EL element, comprising a film that is made of an inorganic material covering said EL element, and a film that is made of an organic material covering said film made of an inorganic material.

U.S. Pat. No. 5,952,778 to Haskal et al. discloses an encapsulated organic light emitting device having an improved protective covering comprising a first layer of passivating metal, a second layer of an inorganic dielectric material and a third layer of polymer.

U.S. Pat. No. 6,570,352 B2 to Graff et al. discloses an encapsulated organic light emitting device comprising a substrate; an organic light emitting layer stack adjacent to the substrate; and at least one first barrier stack adjacent to the organic light emitting device, the at least one first barrier stack comprising at least one first barrier layer and at least one first decoupling layer, wherein the at least one first barrier stack encapsulates the organic light emitting device.

Although the aforementioned references disclose coatings having a wide range of barrier properties, there is continued need for coatings having superior resistance to environmental elements, particularly water vapor and oxygen.

### SUMMARY OF THE INVENTION

The present invention is directed to an electronic package, comprising:

a substrate;

at least one electronic device having electrical contacts, the device positioned on or within the substrate;

a first inorganic barrier coating on the substrate and the electronic device;

a first interfacial coating on the first inorganic barrier coating in a region over the electronic device, wherein the first interfacial coating comprises a cured product of a silicone resin; and

a second inorganic barrier coating on the first interfacial coating and any portion of the first inorganic barrier coating not covered by the first interfacial coating; provided at least a portion of each electrical contact has no coating.

The present invention is also directed to a method of preparing an electronic package, the method comprising:

forming a first inorganic barrier coating on a substrate and at least one electronic device having electrical contacts, the electronic device positioned on or within the substrate;

forming a first interfacial coating on the first inorganic barrier coating in a region over the electronic device, wherein the first interfacial coating comprises a cured product of a silicone resin; and

forming a second inorganic barrier coating on the first interfacial coating and any portion of the first inorganic barrier coating not covered by the first interfacial coating; provided no coating is formed on at least a portion of each electrical contact.

The electronic package of the present invention is typically lighter, thinner, and more durable than conventional electronic packages. Moreover, the composite inorganic barrier and interfacial coatings of the electronic package have a low water vapor transmission rate, typically from 1×10⁻⁷ to 3 g/m²/day. Also, the coatings have low permeability to oxygen and metal ions, such as copper and aluminum. Further, the coatings can be transparent or nontransparent to light in the visible region of the electromagnetic spectrum. Still further, the coatings have high resistance to cracking and low compressive stress.

The method of preparing the electronic package of the present invention can be carried out using conventional equipment and techniques, and readily available silicone compositions. For example inorganic barrier coatings can be deposited using chemical vapor deposition techniques and physical vapor deposition techniques. Moreover, interfacial coatings can be formed using conventional methods of applying and curing silicone compositions. Also, the methods of the present invention are scaleable to high throughput manufacturing processes.

The electronic package of the present invention is useful for fabricating a wide range of consumer electronic products, including light-emitting arrays or displays, calculators, telephones, televisions, and mainframe and personal computers.

### BRIEF DESCRIPTION OF THE DRAWINGS

FIG. 1 shows a cross-sectional view of one embodiment of an electronic package according the present invention.

FIG. 2 shows a cross-sectional view of the aforementioned embodiment of the electronic package, further comprising a second interfacial coating on the second inorganic barrier coating in a region over at least the electronic device, wherein the second interfacial coating comprises a cured product of a silicone resin; and a third inorganic barrier coating on the second interfacial coating and any portion of the second inorganic barrier coating not covered by the second interfacial coating.

### DETAILED DESCRIPTION OF THE INVENTION

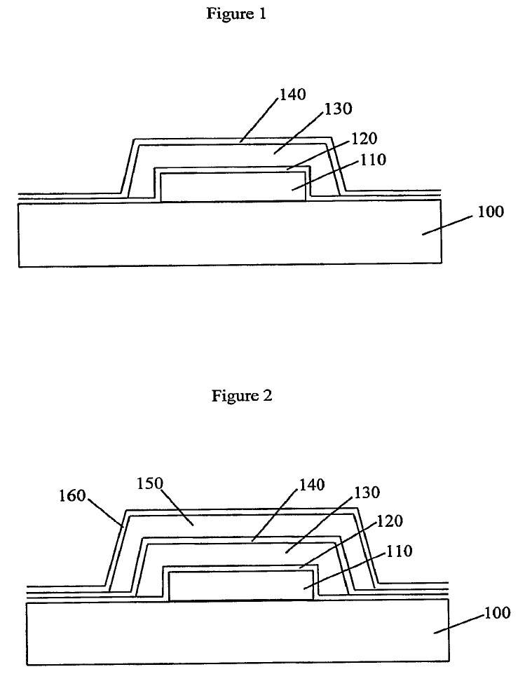

As shown in FIG. 1, one embodiment of an electronic package according to the present invention comprises a substrate 100; at least one electronic device 110 having electrical contacts (not shown), the device 110 positioned on or within the substrate 100; a first inorganic barrier coating 120 on the substrate 100 and the electronic device 110; a first interfacial coating 130 on the first inorganic barrier coating 120 in a region over the electronic device 110, wherein the first interfacial coating 130 comprises a cured product of a silicone resin; and a second inorganic barrier coating 140 on the first interfacial coating 130 and any portion of the first inorganic barrier coating 120 not covered by the first interfacial coating 130; provided at least a portion of each electrical contact has no coating. The substrate can be any rigid or flexible material having a planar, complex, or irregular contour. The substrate can be transparent or nontransparent to light in the visible region (˜400 to ˜700 nm) of the electromagnetic spectrum. Also, the substrate can be an electrical conductor, semiconductor, or nonconductor.

Examples of substrates include, but are not limited to, semiconductors such as silicon, silicon having a surface layer of silicon dioxide, silicon carbide, indium phosphide, and gallium arsenide; quartz; fused quartz; aluminum oxide; ceramics; glass; metal foils; polyolefins such as polyethylene, polypropylene, polystyrene, polyethylene terephthalate (PET), and polyethylene naphthalate; fluorocarbon polymers such as polytetrafluoroethylene and polyvinylfluoride; polyamides such as Nylon; polyimides; polyesters such as poly(methyl methacrylate); epoxy resins; polyethers; polycarbonates; polysulfones; and polyether sulfones.

The electronic package comprises at least one electronic device. The electronic device can be a discrete device or an integrated circuit. The electronic device has electrical contacts for receiving and transmitting electrical signals. In the case of integrated circuits, the electrical contacts or bond pads (i.e., I/O terminals) are usually located on the periphery of the device. The number of bond pads per integrated circuit can range from about 4 to about 2,000, depending on the complexity of the circuit. The bond pads are made of an electrically conductive metal, typically aluminum, copper, or alloys thereof.

The electronic device can be positioned on or within the substrate. For example, bipolar transistors are typically situated in the substrate, whereas thin film transistors, such s field-effect transistors (FETs), are typically situated on the surface of the substrate.

Examples of discrete devices include, but are not limited to, diodes, such as PIN diodes, voltage reference diodes, varactor diodes, Avalanche diodes, DIACs, Gunn diodes, Snap diodes, IMPATT diodes, tunnel diodes, Zener diodes, normal (p-n) diodes, and Shottky diodes; transistors, such as bipolar transistors, including, insulated gate bipolar transistors (IGBTs) and Darlington transistors, and field-effect transistors (FETs), including metal oxide semiconductor FETs (MOSFETs), junction FETs (JFETs), metal-semiconductor FETs (MESFETs), organic FETs, high electron mobility transistors (HEMTs), and thin film transistors (TFTs), including organic field effect transistors; thyristors, for example, DIACs, TRIACs, silicon controlled rectifiers (SCRs), distributed buffer-gate turn-off (DB-GTO) thyristors, gate turn-off (GTO) thyristors, MOFSET controlled thyristors (MCTs), modified anode-gate turn-off (MA-GTO) thyristors, static induction thyristors (SIThs), and field controlled thyristors (FCThs); varistors; resistors; condensers; capacitors; thermistors; and optoelectronic devices, such as photodiodes, solar cells (for example CIGS solar cells and organic photovoltaic cells), phototransistors, photomultipliers, integrated optical circuit (IOC) elements, light-dependent resistors, laser diodes, light-emitting diodes (LEDs), and organic light-emitting diodes (OLEDs), including small-molecule OLEDs (SM-OLEDs) and polymer light-emitting diodes (PLEDs).

Examples of integrated circuits include, but are not limited to, monolithic integrated circuits, such as memory ICs, including RAM (random-access memory), including DRAM and SRAM, and ROM (read-only memory); logic circuits; analog integrated circuits; hybrid integrated circuits, including thin-film hybrid ICs and thick-film hybrid ICs; thin film batteries; solar cells, and fuel cells.

The first inorganic barrier coating can be any barrier coating comprising an inorganic material having a low permeability to water vapor (moisture). The inorganic material can be an electrical conductor, nonconductor, or semiconductor.

The first inorganic barrier coating can be a single layer coating comprising one layer of an inorganic material or a multiple layer coating comprising two or more layers of at least two different inorganic materials, where directly adjacent layers comprise different inorganic materials (i.e., inorganic materials have a different composition and/or property). When the layer of inorganic material in a single layer coating comprises two or more elements (e.g. TiN), the layer can be a gradient layer, where the composition of the layer changes with thickness. Similarly, when at least one layer of inorganic material in a multiple layer coating comprises two or more elements, the layer can be a gradient layer. The multiple layer coating typically comprises from 2 to 7 layers, alternatively from 2 to 5 layers, alternatively from 2 to 3 layers.

The single layer inorganic barrier coating typically has a thickness of from 0.03 to 3 μm, alternatively from 0.1 to 1 μm, alternatively from 0.2 to 0.8 μm. The multiple layer inorganic barrier coating typically has a thickness of from 0.06 to 5 μm, alternatively from 0.1 to 3 μm, alternatively from 0.2 to 2.5 μm. When the thickness of the inorganic barrier coating is less than 0.03 μm, the permeability of the coating to moisture may be too high for some applications. When the thickness of the inorganic barrier coating is greater than 5 μm, the inorganic barrier coating may be susceptible to cracking.

The first inorganic barrier coating may be transparent or nontransparent to light in the visible region (˜400 to ˜700 nm) of the electromagnetic spectrum. A transparent inorganic barrier coating typically has a percent transmittance of at least 30%, alternatively at least 60%, alternatively at least 80%, for light in the visible region of the electromagnetic spectrum.

Examples of inorganic materials include, but are not limited to, metals such as aluminum, calcium, magnesium, nickel, and gold; metal alloys such as aluminum magnesium alloy, silver magnesium alloy, lithium aluminum alloy, indium magnesium alloy, and aluminum calcium alloy; oxides such as silicon dioxide, aluminum oxide, titanium(II) oxide, titanium(III) oxide, barium oxide, beryllium oxide, magnesium oxide, tin(II) oxide, tin(IV) oxide, indium(III) oxide, lead(II) oxide, lead(IV) oxide, zinc oxide, tantalum(V) oxide, yttrium(III) oxide, phosphorus pentoxide, boric oxide, zirconium(IV) oxide, and calcium oxide; mixed oxides such as indium tin oxide (ITO), indium zinc oxide (IZO), and indium cerium oxide; nitrides such as silicon nitride, titanium nitride, aluminum nitride, indium(III) nitride, and gallium nitride; mixed nitrides such as aluminum silicon nitride; oxynitrides such as silicon oxynitride, aluminum oxynitride, and boron oxynitride; carbides such as silicon carbide, aluminum carbide, boron carbide, and calcium carbide; oxycarbides such as silicon oxycarbide; mixed oxynitrides such as aluminum silicon oxynitrides and titanium silicon oxynitrides; fluorides such as magnesium fluoride and calcium fluoride; and carbide nitrides such as silicon carbide nitride.

The first inorganic barrier coating can be formed as described below in the method of preparing the electronic package of the present invention.

The first interfacial coating is on the first inorganic barrier coating in a region over the electronic device. Typically, the region over the electronic device is slightly greater than the dimensions of the device. For example, the region over the electronic device is typically from 105 to 110% greater, alternatively from 110 to 120% greater than the dimensions of the device.

The first interfacial coating comprises a cured product of at least one silicone resin. As used herein, the term “cured product of a silicone resin” refers to a cross-linked silicone resin having a three-dimensional network structure. The first interfacial coating can be a single layer coating comprising one layer of a cured product of a silicone resin, or a multiple layer coating comprising two or more layers of at least two different cured products of silicone resins, where directly adjacent layers comprise different cured products (i.e., cured products have a different composition and/or property). The multiple layer coating typically comprises from 2 to 7 layers, alternatively from 2 to 5 layers, alternatively from 2 to 3 layers. The single layer interfacial coating typically has a thickness of from 0.03 to 30 μm, alternatively from 0.1 to 10 μm, alternatively from 0.1 to 1.5 μm. The multiple layer interfacial coating typically has a thickness of from 0.06 to 30 μm, alternatively from 0.2 to 10 μm, alternatively 0.2 to 3 μm. When the thickness of the interfacial coating is less than 0.03 μm, the coating may become discontinuous. When the thickness of the interfacial coating is greater than 30 μm, the coating may exhibit reduced adhesion and/or cracking. The first interfacial coating typically exhibits high transparency. For example, the first interfacial coating typically has a percent transmittance of at least 90%, alternatively at least 92%, alternatively at least 94%, for light in the visible region (˜400 to 700 nm) of the electromagnetic spectrum.

The silicone resin, methods of preparing the resin, and methods of preparing the first interfacial layer are described below in the method of preparing the electronic package of the present invention.

The second inorganic barrier coating is on the first interfacial coating and any portion of the first inorganic barrier coating not covered by the first interfacial coating. The second inorganic barrier coating is as described and exemplified above for the first inorganic barrier coating of the electronic package.

The electronic package of the present invention can further comprise at least two alternating interfacial and inorganic barrier coatings on the second inorganic barrier coating. For example, as shown in FIG. 2, the previous embodiment of the electronic package can further comprise a second interfacial coating 150 on the second inorganic barrier coating 140 in a region over at least the electronic device 110, wherein the second interfacial coating 150 comprises a cured product of a silicone resin; and a third inorganic barrier coating 160 on the second interfacial coating 150 and any portion of the second inorganic barrier coating 140 not covered by the second interfacial coating 150.

A method of preparing an electronic package according to the present invention, comprises:

forming a first inorganic barrier coating on a substrate and at least one electronic device having electrical contacts, the electronic device positioned on or within the substrate;

forming a first interfacial coating on the first inorganic barrier coating in a region over the electronic device, wherein the first interfacial coating comprises a cured product of a silicone resin; and

forming a second inorganic barrier coating on the first interfacial coating and any portion of the first inorganic barrier coating not covered by the first interfacial coating; provided no coating is formed on at least a portion of each electrical contact.

According to the preceding method of preparing an electronic package, a first inorganic barrier coating is formed on a substrate and at least one electronic device having electrical contacts, where the electronic device is positioned on or within the substrate. The first inorganic barrier coating, the substrate, and the electronic device are as described and exemplified above for the electronic package.

Methods of forming inorganic barrier coatings are well known in the art. For example inorganic barrier coatings can be deposited using chemical vapor deposition techniques, such as thermal chemical vapor deposition, plasma enhanced chemical vapor deposition, photochemical vapor deposition, electron cyclotron resonance, inductively coupled plasma, magnetically confined plasma, and jet vapor deposition; and physical vapor deposition techniques, such as RF sputtering, atomic layer deposition, and DC magnetron sputtering.

A first interfacial coating is formed on the first inorganic barrier coating in a region over the electronic device, wherein the first interfacial coating comprises a cured product of a silicone resin. The first interfacial coating is as described and exemplified above for the electronic package of the present invention.

The first interfacial coating can be formed using a variety of methods. For example, the first interfacial coating can be formed by a first method comprising (i) applying a curable silicone composition comprising a silicone resin on the first inorganic barrier coating in a region over the electronic device to form a film, and (ii) curing the silicone resin of the film.

The curable silicone composition can be any curable silicone composition comprising at least one silicone resin. Curable silicone compositions and methods for their preparation are well known in the art. Examples of curable silicone compositions include, but are not limited to, hydrosilylation-curable silicone compositions, condensation-curable silicone compositions, radiation-curable silicone compositions, and peroxide-curable silicone compositions.

The silicone resin of the curable silicone composition can contain T siloxane units, T and Q siloxane units, or T and/or Q siloxane units in combination with M and/or D siloxane units. For example, the silicone resin can be a T resin, a TQ resin, an MT resin, a DT resin, an MDT resin, an MQ resin, a DQ resin, an MDQ resin, an MTQ resin, a DTQ resin, or an MDTQ resin.

The silicone resin typically contains silicon-bonded reactive groups capable of reacting in the presence or absence of a catalyst to form a cured product of the silicone resin. Examples of silicon-bonded reactive groups include, but are not limited to, —H, alkenyl, alkynyl, —OH, a hydrolysable group, alkenyl ether, acryloyloxyalkyl, substituted acryloyloxyalkyl, and an epoxy-substituted organic group.

The silicone resin typically has a weight-average molecular weight (M_{w}) of from 500 to 1,000,000, alternatively from 1,000 to 100,000, alternatively from 1,000 to 50,000, alternatively from 1,000 to 20,000, alternatively form 1,000 to 10,000, where the molecular weight is determined by gel permeation chromatography employing a refractive index detector and polystyrene standards.

A hydrosilylation-curable silicone composition typically comprises a silicone resin having an average of at least two silicon-bonded alkenyl groups or silicon-bonded hydrogen atoms per molecule; an organosilicon compound in an amount sufficient to cure the silicone resin, wherein the organosilicon compound has an average of at least two silicon-bonded hydrogen atoms or silicon-bonded alkenyl groups per molecule capable of reacting with the silicon-bonded alkenyl groups or silicon-bonded hydrogen atoms in the silicone resin; and a catalytic amount of a hydrosilylation catalyst.

According to a first embodiment, the hydrosilylation-curable silicone composition comprises (A) a silicone resin having the formula (R¹R²₂SiO_{1/2})_{w}(R²₂SiO_{2/2})ₓ (R²SiO_{3/2})_{y}(SiO_{4/2})_{z} (I), wherein each R¹ is independently C₁ to C₁₀ hydrocarbyl or C₁ to C₁₀ halogen-substituted hydrocarbyl, both free of aliphatic unsaturation, each R² is independently R¹ or alkenyl, w is from 0 to 0.95, x is from 0 to 0.95, y is from 0 to 1, z is from 0 to 0.9, y+z is from 0.1 to 1, and w+x+y+z=1, provided the silicone resin has an average of at least two silicon-bonded alkenyl groups per molecule; (B) an organosilicon compound having an average of at least two silicon-bonded hydrogen atoms per molecule in an amount sufficient to cure the silicone resin; and (C) a catalytic amount of a hydrosilylation catalyst.

Component (A) is at least one silicone resin having the formula (R¹R²₂SiO_{1/2})_{w}(R²₂SiO_{2/2})ₓ(R²SiO_{3/2})_{y}(SiO_{4/2})_{z}(I), wherein each R¹ is independently C₁ to C₁₀ hydrocarbyl or C₁ to C₁₀ halogen-substituted hydrocarbyl, both free of aliphatic unsaturation, each R² is independently R¹ or alkenyl, w is from 0 to 0.95, x is from 0 to 0.95, y is from 0 to 1, z is from 0 to 0.9, y+z is from 0.1 to 1, and w+x+y+z=1, provided the silicone resin has an average of at least two silicon-bonded alkenyl groups per molecule. The hydrocarbyl and halogen-substituted hydrocarbyl groups represented by R¹ are free of aliphatic unsaturation and typically have from 1 to 10 carbon atoms, alternatively from 1 to 6 carbon atoms. Acyclic hydrocarbyl and halogen-substituted hydrocarbyl groups containing at least 3 carbon atoms can have a branched or unbranched structure. Examples of hydrocarbyl groups represented by R¹ include, but are not limited to, alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, octyl, nonyl, and decyl; cycloalkyl, such as cyclopentyl, cyclohexyl, and methylcyclohexyl; aryl, such as phenyl and naphthyl; alkaryl, such as tolyl and xylyl; and aralkyl, such as benzyl and phenethyl. Examples of halogen-substituted hydrocarbyl groups represented by R¹ include, but are not limited to, 3,3,3-trifluoropropyl, 3-chloropropyl, chlorophenyl, dichlorophenyl, 2,2,2-trifluoroethyl, 2,2,3,3-tetrafluoropropyl, and 2,2,3,3,4,4,5,5-octafluoropentyl.

The alkenyl groups represented by R², which may be the same or different, typically have from 2 to about 10 carbon atoms, alternatively from 2 to 6 carbon atoms, and are exemplified by, but not limited to, vinyl, allyl, butenyl, hexenyl, and octenyl.

In the formula (I) of the silicone resin, the subscripts w, x, y, and z are mole fractions. The subscript w typically has a value of from 0 to 0.95, alternatively from 0 to 0.8, alternatively from 0 to 0.2; the subscript x typically has a value of from 0 to 0.95, alternatively from 0 to 0.8, alternatively from 0 to 0.5; the subscript y typically has a value of from 0 to 1, alternatively from 0.3 to 1, alternatively from 0.5 to 1; the subscript z typically has a value of from 0 to 0.9, alternatively from 0 to 0.5, alternatively from 0 to 0.1; and the sum y+z typically has value of from 0.1 to 1, alternatively from 0.2 to 1, alternatively from 0.5 to 1, alternatively 0.8 to 1.

Typically at least 50 mol %, alternatively at least 65 mol %, alternatively at least 80 mol % of the groups R² in the silicone resin are alkenyl. The term “mol % of the groups R² in the silicone resin are alkenyl” is defined as the ratio of the number of moles of silicon-bonded alkenyl groups in the silicone resin to the total number of moles of the groups R² in the resin, multiplied by 100.

The silicone resin typically contains less than 10% (w/w), alternatively less than 5% (w/w), alternatively less than 2% (w/w), of silicon-bonded hydroxy groups, as determined by ²⁹Si NMR.

Examples of silicone resins suitable for use as component (A) include, but are not limited to, resins having the following formulae:

(Vi₂MeSiO_{1/2})_{0.25}(PhSiO_{3/2})_{0.75}, (ViMe₂SiO_{1/2})_{0.25}(PhSiO_{3/2})_{0.75}, (ViMe₂SiO_{1/2})_{0.25}(MeSiO_{3/2})_{0.25}(PhSiO_{3/2})_{0.50}, (ViMe₂SiO_{1/2})_{0.15}(PhSiO_{3/2})_{0.75}(SiO_{4/2})_{0.1}, and (Vi₂MeSiO_{1/2})_{0.15}(ViMe₂SiO_{1/2})_{0.1}(PhSiO_{3/2})_{0.75}, where Me is methyl, Vi is vinyl, Ph is phenyl, and the numerical subscripts outside the parenthesis denote mole fractions. Also, in the preceding formulae, the sequence of units is unspecified.

Component (A) can be a single silicone resin or a mixture comprising two or more different silicone resins, each as described above.

Methods of preparing silicone resins containing silicon-bonded alkenyl groups are well known in the art; many of these resins are commercially available. These resins are typically prepared by cohydrolyzing the appropriate mixture of chlorosilane precursors in an organic solvent, such as toluene. For example, a silicone resin consisting essentially of R¹R²₂SiO_{1/2} units and R²SiO_{3/2} units can be prepared by cohydrolyzing a compound having the formula R¹R²₂SiCl and a compound having the formula R²SiCl₃ in toluene, where R¹ and R² are as defined and exemplified above. The aqueous hydrochloric acid and silicone hydrolyzate are separated and the hydrolyzate is washed with water to remove residual acid and heated in the presence of a mild condensation catalyst to “body” the resin to the requisite viscosity. If desired, the resin can be further treated with a condensation catalyst in an organic solvent to reduce the content of silicon-bonded hydroxy groups. Alternatively, silanes containing hydrolysable groups other than chloro, such —Br, —I, —OCH₃, —OC(O)CH₃, —N(CH₃)₂, NHCOCH₃, and —SCH₃, can be utilized as starting materials in the cohydrolysis reaction. The properties of the resin products depend on the types of silanes, the mole ratio of silanes, the degree of condensation, and the processing conditions.

Component (B) is at least one organosilicon compound having an average of at least two silicon-bonded hydrogen atoms per molecule in an amount sufficient to cure the silicone resin of component (A).

The organosilicon compound has an average of at least two silicon-bonded hydrogen atoms per molecule, alternatively at least three silicon-bonded hydrogen atoms per molecule. It is generally understood that cross-linking occurs when the sum of the average number of alkenyl groups per molecule in component (A) and the average number of silicon-bonded hydrogen atoms per molecule in component (B) is greater than four.

The organosilicon compound can be an organohydrogensilane or an organohydrogensiloxane. The organohydrogensilane can be a monosilane, disilane, trisilane, or polysilane. Similarly, the organohydrogensiloxane can be a disiloxane, trisiloxane, or polysiloxane. The structure of the organosilicon compound can be linear, branched, cyclic, or resinous. Cyclosilanes and cyclosiloxanes typically have from 3 to 12 silicon atoms, alternatively from 3 to 10 silicon atoms, alternatively from 3 to 4 silicon atoms. In acyclic polysilanes and polysiloxanes, the silicon-bonded hydrogen atoms can be located at terminal, pendant, or at both terminal and pendant positions.

Examples of organohydrogensilanes include, but are not limited to, diphenylsilane, 2-chloroethylsilane, bis[(p-dimethylsilyl)phenyl]ether, 1,4-dimethyldisilylethane, 1,4-bis(dimethylsilyl)benzene, 1,3,5-tris(dimethylsilyl)benzene, 1,3,5-trimethyl-1,3,5-trisilane, poly(methylsilylene)phenylene, and poly(methylsilylene)methylene.

Examples of organohydrogensiloxanes include, but are not limited to, 1,1,3,3-tetramethyldisiloxane, 1,1,3,3-tetraphenyldisiloxane, phenyltris(dimethylsiloxy)silane, 1,3,5-trimethylcyclotrisiloxane, a trimethylsiloxy-terminated poly(methylhydrogensiloxane), a trimethylsiloxy-terminated poly(dimethylsiloxane/methylhydrogensiloxane), a dimethylhydrogensiloxy-terminated poly(methylhydrogensiloxane), and a resin consisting essentially of HMe₂SiO_{1/2} units, Me₃SiO_{1/2} units, and SiO_{4/2} units, wherein Me is methyl.

Component (C) of the hydrosilylation-curable silicone composition is at least one hydrosilylation catalyst that promotes the addition reaction of component (A) with component (B). The hydrosilylation catalyst can be any of the well-known hydrosilylation catalysts comprising a platinum group metal, a compound containing a platinum group metal, or a microencapsulated platinum group metal-containing catalyst. Platinum group metals include platinum, rhodium, ruthenium, palladium, osmium and iridium. Preferably, the platinum group metal is platinum, based on its high activity in hydrosilylation reactions.

Preferred hydrosilylation catalysts include the complexes of chloroplatinic acid and certain vinyl-containing organosiloxanes disclosed by Willing in U.S. Pat. No. 3,419,593, which is hereby incorporated by reference. A preferred catalyst of this type is the reaction product of chloroplatinic acid and 1,3-diethenyl-1,1,3,3-tetramethyldisiloxane.

The hydrosilylation catalyst can also be a microencapsulated platinum group metal-containing catalyst comprising a platinum group metal encapsulated in a thermoplastic resin. Compositions containing microencapsulated hydrosilylation catalysts are stable for extended periods of time, typically several months or longer, under ambient conditions, yet cure relatively rapidly at temperatures above the melting or softening point of the thermoplastic resin(s). Microencapsulated hydrosilylation catalysts and methods of preparing them are well known in the art, as exemplified in U.S. Pat. No. 4,766,176 and the references cited therein; and U.S. Pat. No. 5,017,654.

Component (C) can be a single hydrosilylation catalyst or a mixture comprising two or more different catalysts that differ in at least one property, such as structure, form, platinum group metal, complexing ligand, and thermoplastic resin.

The concentration of component (C) is sufficient to catalyze the addition reaction of component (A) with component (B). Typically, the concentration of component (C) is sufficient to provide from 0.1 to 1000 ppm of a platinum group metal, preferably from 1 to 500 ppm of a platinum group metal, and more preferably from 5 to 150 ppm of a platinum group metal, based on the combined weight of components (A) and (B). The rate of cure is very slow below 0.1 ppm of platinum group metal. The use of more than 1000 ppm of platinum group metal results in no appreciable increase in cure rate, and is therefore uneconomical.

According to a second embodiment, the hydrosilylaton-curable silicone composition comprises (A′) a silicone resin having the formula (R¹R³₂SiO_{1/2})_{w}(R³₂SiO_{2/2})ₓ (R³SiO_{3/2})_{y}(SiO_{4/2})_{z} (II), wherein each R¹ is independently C₁ to C₁₀ hydrocarbyl or C₁ to C₁₀ halogen-substituted hydrocarbyl, both free of aliphatic unsaturation, each R³ is independently R¹ or —H, w is from 0 to 0.95, x is from 0 to 0.95, y is from 0 to 1, z is from 0 to 0.9, y+z is from 0.1 to 1, and w+x+y+z−1, provided the silicone resin has an average of at least two silicon-bonded hydrogen atoms per molecule; (B′) an organosilicon compound having an average of at least two silicon-bonded alkenyl groups per molecule in an amount sufficient to cure the silicone resin; and (C) a catalytic amount of a hydrosilylation catalyst.

Component (A′) is at least one silicone resin having the formula (R¹R³₂SiO_{1/2})_{w}(R³₂SiO_{2/2})ₓ(R³SiO_{3/2})_{y}(SiO_{4/2})_{z}(II), wherein each R¹ is independently C₁ to C₁₀ hydrocarbyl or C₁ to C₁₀ halogen-substituted hydrocarbyl, both free of aliphatic unsaturation, each R³ is independently R¹ or —H, w is from 0 to 0.95, x is from 0 to 0.95, y is from 0 to 1, z is from 0 to 0.9, y+z is from 0.1 to 1, and w+x+y+z=1, provided the silicone resin has an average of at least two silicon-bonded hydrogen atoms per molecule. In the formula (II), R¹, w, x, y, z, and y+z are as described and exemplified above for the silicone resin having the formula (I).

Typically at least 50 mol %, alternatively at least 65 mol %, alternatively at least 80 mol % of the groups R³ in the silicone resin are hydrogen. The term “mol % of the groups R³ in the silicone resin are hydrogen” is defined as the ratio of the number of moles of silicon-bonded hydrogen atoms in the silicone resin to the total number of moles of the groups R³ in the resin, multiplied by 100.

The silicone resin typically contains less than 10% (w/w), alternatively less than 5% (w/w), alternatively less than 2% (w/w), of silicon-bonded hydroxy groups, as determined by ²⁹Si NMR.

Examples of silicone resins suitable for use as component (A′) include, but are not limited to, resins having the following formulae:

(HMe₂SiO_{1/2})_{0.25}(PhSiO_{3/2})_{0.75}, (HMeSiO_{2/2})_{0.3}(PhSiO_{3/2})_{0.6}(MeSiO_{3/2})_{0.1}, and (Me₃SiO_{1/2})_{0.1}(H₂SiO_{2/2})_{0.1}(MeSiO_{3/2})_{0.4}(PhSiO_{3/2})_{0.4}, where Me is methyl, Ph is phenyl, and the numerical subscripts outside the parenthesis denote mole fractions. Also, in the preceding formulae, the sequence of units is unspecified.

Component (A′) can be a single silicone resin or a mixture comprising two or more different silicone resins, each as described above.

Methods of preparing silicone resins containing silicon-bonded hydrogen atoms are well known in the art; many of these resins are commercially available. Silicone resins are typically prepared by cohydrolyzing the appropriate mixture of chlorosilane precursors in an organic solvent, such as toluene. For example, a silicone resin consisting essentially of R¹R³₂SiO_{1/2} units and R³SiO_{3/2} units can be prepared by cohydrolyzing a compound having the formula R¹R³₂SiCl and a compound having the formula R³SiCl₃ in toluene, where R¹ and R³ are as described and exemplified above. The aqueous hydrochloric acid and silicone hydrolyzate are separated and the hydrolyzate is washed with water to remove residual acid and heated in the presence of a mild non-basic condensation catalyst to “body” the resin to the requisite viscosity. If desired, the resin can be further treated with a non-basic condensation catalyst in an organic solvent to reduce the content of silicon-bonded hydroxy groups. Alternatively, silanes containing hydrolysable groups other than chloro, such —Br, —I, —OCH₃, —OC(O)CH₃, —N(CH₃)₂, NHCOCH₃, and —SCH₃, can be utilized as starting materials in the cohydrolysis reaction. The properties of the resin products depend on the types of silanes, the mole ratio of silanes, the degree of condensation, and the processing conditions.

Component (B′) is at least one organosilicon compound having an average of at least two silicon-bonded alkenyl groups per molecule in an amount sufficient to cure the silicone resin of component (A′).

The organosilicon compound contains an average of at least two silicon-bonded alkenyl groups per molecule, alternatively at least three silicon-bonded alkenyl groups per molecule. It is generally understood that cross-linking occurs when the sum of the average number of silicon-bonded hydrogen atoms per molecule in component (A′) and the average number of silicon-bonded alkenyl groups per molecule in component (B′) is greater than four.

The organosilicon compound can be an organosilane or an organosiloxane. The organosilane can be a monosilane, disilane, trisilane, or polysilane. Similarly, the organosiloxane can be a disiloxane, trisiloxane, or polysiloxane. The structure of the organosilicon compound can be linear, branched, cyclic, or resinous. Cyclosilanes and cyclosiloxanes typically have from 3 to 12 silicon atoms, alternatively from 3 to 10 silicon atoms, alternatively from 3 to 5 silicon atoms. In acyclic polysilanes and polysiloxanes, the silicon-bonded alkenyl groups can be located at terminal, pendant, or at both terminal and pendant positions.

Examples of organosilanes suitable for use as component (B′) include, but are not limited to, silanes having the following formulae:

Vi₄Si, PhSiVi₃, MeSiVi₃, PhMeSiVi₂, Ph₂SiVi₂, and PhSi(CH₂CH═CH₂)₃, where Me is methyl, Ph is phenyl, and Vi is vinyl.

Examples of organosiloxanes suitable for use as component (B′) include, but are not limited to, siloxanes having the following formulae:

PhSi(OSiMe₂Vi)₃, Si(OSiMe₂Vi)₄, MeSi(OSiMe₂Vi)₃, and Ph₂Si(OSiMe₂Vi)₂, where Me is methyl, Ph is phenyl, and Vi is vinyl.

Component (B′) can be a single organosilicon compound or a mixture comprising two or more different organosilicon compounds, each as described above. For example component (B′) can be a single organosilane, a mixture of two different organosilanes, a single organosiloxane, a mixture of two different organosiloxanes, or a mixture of an organosilane and an organosiloxane.

The concentration of component (B′) is sufficient to cure (cross-link) the silicone resin of component (A′). The exact amount of component (B′) depends on the desired extent of cure, which generally increases as the ratio of the number of moles of silicon-bonded alkenyl groups in component (B′) to the number of moles of silicon-bonded hydrogen atoms in component (A′) increases. The concentration of component (B′) is typically sufficient to provide from 0.4 to 2 moles of silicon-bonded alkenyl groups, alternatively from 0.8 to 1.5 moles of silicon-bonded alkenyl groups, alternatively from 0.9 to 1.1 moles of silicon-bonded alkenyl groups, per mole of silicon-bonded hydrogen atoms in component (A′).

Methods of preparing organosilanes and organosiloxanes containing silicon-bonded alkenyl groups are well known in the art; many of these compounds are commercially available.

Component (C) of the second embodiment of the hydrosilylation-curable silicone composition is as described and exemplified above for component (C) of the first embodiment.

The hydrosilylation-curable silicone composition of the present method can comprise additional ingredients, provided the ingredient does not prevent the silicone composition from curing to form the first interfacial coating, described above, of the electronic package. Examples of additional ingredients include, but are not limited to, hydrosilylation catalyst inhibitors, such as 3-methyl-3-penten-1-yne, 3,5-dimethyl-3-hexen-1-yne, 3,5-dimethyl-1-hexyn-3-ol, 1-ethynyl-1-cyclohexanol, 2-phenyl-3-butyn-2-ol, vinylcyclosiloxanes, and triphenylphosphine; adhesion promoters, such as the adhesion promoters taught in U.S. Pat. Nos. 4,087,585 and 5,194,649; dyes; pigments; anti-oxidants; heat stabilizers; UV stabilizers; flame retardants; flow control additives; and diluents, such as organic solvents and reactive diluents.

The condensation-curable silicone composition typically comprises a silicone resin having an average of at least two silicon-bonded hydrogen atoms, hydroxy groups, or hydrolysable groups per molecule and, optionally, a cross-linking agent having silicon-bonded hydrolysable groups and/or a condensation catalyst.

According to one embodiment, the condensation-curable silicone composition comprises a silicone resin having the formula (R⁴R⁵₂SiO_{1/2})_{w}(R⁵₂SiO_{2/2})ₓ (R⁵SiO_{3/2})_{y}(SiO_{4/2})_{z} (III), wherein each R⁴ is independently C₁ to C₁₀ hydrocarbyl or C₁ to C₁₀ halogen-substituted hydrocarbyl, each R⁵ is independently R⁴, —H, —OH, or a hydrolysable group, w is from 0 to 0.95, x is from 0 to 0.95, y is from 0 to 1, z is from 0 to 0.9, y+z is from 0.1 to 1, and w+x+y+z=1, provided the silicone resin has an average of at least two silicon-bonded hydrogen atoms, hydroxy groups, or hydrolysable groups per molecule. In the formula (III), w, x, y, z, and y+z are as described and exemplified above for the silicone resin having the formula (I).

The hydrocarbyl and halogen-substituted hydrocarbyl groups represented by R⁴ typically have from 1 to 10 carbon atoms, alternatively from 1 to 6 carbon atoms, alternatively from 1 to 4 carbon atoms. Acyclic hydrocarbyl and halogen-substituted hydrocarbyl groups containing at least 3 carbon atoms can have a branched or unbranched structure. Examples of hydrocarbyl groups include, but are not limited to, alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, octyl, nonyl, and decyl; cycloalkyl, such as cyclopentyl, cyclohexyl, and methylcyclohexyl; aryl, such as phenyl and naphthyl; alkaryl, such as tolyl and xylyl; aralkyl, such as benzyl and phenethyl; alkenyl, such as vinyl, allyl, and propenyl; arylalkenyl, such as styryl and cinnamyl; and alkynyl, such as ethynyl and propynyl. Examples of halogen-substituted hydrocarbyl groups include, but are not limited to, 3,3,3-trifluoropropyl, 3-chloropropyl, chlorophenyl, dichlorophenyl, 2,2,2-trifluoroethyl, 2,2,3,3-tetrafluoropropyl, and 2,2,3,3,4,4,5,5-octafluoropentyl. As used herein the term “hydrolysable group” means the silicon-bonded group reacts with water in either the presence or absence of a catalyst at any temperature from room temperature (˜23±2° C.) to 100° C. within several minutes, for example thirty minutes, to form a silanol (Si—OH) group. Examples of hydrolysable groups represented by R⁵ include, but are not limited to, —Cl, —Br, —OR⁶, —OCH₂CH₂OR⁶, CH₃C(═O)O—, Et(Me)C═N—O—, CH₃C(═O)N(CH₃)—, and —ONH₂, wherein R⁶ is C₁ to C₈ hydrocarbyl or C₁ to C₈ halogen-substituted hydrocarbyl.

The hydrocarbyl and halogen-substituted hydrocarbyl groups represented by R⁶ typically have from 1 to 8 carbon atoms, alternatively from 3 to 6 carbon atoms. Acyclic hydrocarbyl and halogen-substituted hydrocarbyl groups containing at least 3 carbon atoms can have a branched or unbranched structure. Examples of hydrocarbyl include, but are not limited to, unbranched and branched alkyl, such as methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, and octyl; cycloalkyl, such as cyclopentyl, cyclohexyl, and methylcyclohexyl; phenyl; alkaryl, such as tolyl and xylyl; aralkyl, such as benzyl and phenethyl; alkenyl, such as vinyl, allyl, and propenyl; arylalkenyl, such as styryl; and alkynyl, such as ethynyl and propynyl. Examples of halogen-substituted hydrocarbyl groups include, but are not limited to, 3,3,3-trifluoropropyl, 3-chloropropyl, chlorophenyl, and dichlorophenyl.

Typically, at least 10 mol %, alternatively at least 50 mol %, alternatively at least 80 mol % of the groups R⁵ in the silicone resin are hydrogen, hydroxy, or a hydrolysable group. The term “mol % of the groups R⁵ in the silicone resin are in the silicone resin are hydrogen, hydroxy, or a hydrolysable group” is defined as the ratio of the number of moles of silicon-bonded hydrogen, hydroxy, or a hydrolysable groups in the silicone resin to the total number of moles of the groups R⁵ in the resin, multiplied by 100.

Examples of silicone resins having the formula (III) include, but are not limited to, resins having the following formulae:

(MeSiO_{3/2})ₙ, (PhSiO_{3/2})ₙ, (Me₃SiO_{1/2})_{0.8}(SiO_{4/2})_{0.2}, (MeSiO_{3/2})_{0.67}(PhSiO_{3/2})_{0.33}, (MeSiO_{3/2})_{0.45}(PhSiO_{3/2})_{0.40}(Ph₂SiO_{2/2})_{0.1}(PhMeSiO_{2/2})_{0.05}, (PhSiO_{3/2})_{0.4}(MeSiO_{3/2})_{0.45}(PhSiO_{3/2})_{0.1}(PhMeSiO_{2/2})_{0.05}, and (PhSiO_{3/2})_{0.4}(MeSiO_{3/2})_{0.1}(PhMeSiO_{2/2})_{0.5}, where Me is methyl, Ph is phenyl, the numerical subscripts outside the parenthesis denote mole fractions, and the subscript n has a value such that the silicone resin has a weight-average molecular weight of from 500 to 1,000,000. Also, in the preceding formulae, the sequence of units is unspecified.

The condensation-curable silicone composition can comprise a single silicone resin or a mixture comprising two or more different silicone resins, each as described above.

Methods of preparing silicone resins containing silicon-bonded hydrogen atoms, hydroxy groups, or hydrolysable groups are well known in the art; many of these resins are commercially available. Silicone resins are typically prepared by cohydrolyzing the appropriate mixture of silane precursors in an organic solvent, such as toluene. For example, a silicone resin can be prepared by cohydrolyzing a silane having the formula R⁴R⁵₂SiX and a silane having the formula R⁵SiX₃ in toluene, where R⁴ is C₁ to C₁₀ hydrocarbyl or C₁ to C₁₀ halogen-substituted hydrocarby, R⁵ is R⁴, —H, or a hydrolysable group, and X is a hydrolysable group, provided when R⁵ is a hydrolysable group, X is more reactive in the hydrolysis reaction than R⁵. The aqueous hydrochloric acid and silicone hydrolyzate are separated and the hydrolyzate is washed with water to remove residual acid and heated in the presence of a mild condensation catalyst to “body” (i.e., condense) the resin to the requisite viscosity. If desired, the resin can be further treated with a condensation catalyst in an organic solvent to reduce the content of silicon-bonded hydroxy groups.

The condensation-curable silicone composition can comprise additional ingredients, provided the ingredient does not prevent the silicone resin from curing to form the first interfacial coating, described above, of the electronic package. Examples of additional ingredients include, but are not limited to, adhesion promoters; dyes; pigments; anti-oxidants; heat stabilizers; UV stabilizers; flame retardants; flow control additives; organic solvents, cross-linking agents, and condensation catalysts.

For example the condensation-curable silicone composition can further comprises a cross-linking agent and/or a condensation catalyst. The cross-linking agent can have the formula R⁶_{q}SiX_{4-q}, wherein R⁶ is C₁ to C₈ hydrocarbyl or C₁ to C₈ halogen-substituted hydrocarbyl, X is a hydrolysable group, and q is 0 or 1. The hydrocarbyl and halogen-substituted hydrocarbyl groups represented by R⁶ are as described and exemplified above. Also, the hydrolysable groups represented by X are as described and exemplified above for R⁵.

Examples of cross-linking agents include, but are not limited to, alkoxy silanes such as MeSi(OCH₃)₃, CH₃Si(OCH₂CH₃)₃, CH₃Si(OCH₂CH₂CH₃)₃, CH₃Si[O(CH₂)₃CH₃]₃, CH₃CH₂Si(OCH₂CH₃)₃, C₆H₁₅Si(OCH₃)₃, C₆H₅CH₂Si(OCH₃)₃, C₆H₅Si(OCH₂CH₃)₃, CH₂═CHSi(OCH₃)₃, CH₂═CHCH₂Si(OCH₃)₃, CF₃CH₂CH₂Si(OCH₃)₃, CH₃Si(OCH₂CH₂OCH₃)₃, CF₃CH₂CH₂Si(OCH₂CH₂OCH₃)₃, CH₂═CHSi(OCH₂CH₂OCH₃)₃, CH₂═CHCH₂Si(OCH₂CH₂OCH₃)₃, C₆H₅Si(OCH₂CH₂OCH₃)₃, Si(OCH₃)₄, Si(OC₂H₅)₄, and Si(OC₃H₇)₄; organoacetoxysilanes such as CH₃Si(OCOCH₃)₃, CH₃CH₂Si(OCOCH₃)₃, and CH₂═CHSi(OCOCH₃)₃; organoiminooxysilanes such as CH₃Si[O—N═C(CH₃)CH₂CH₃]₃, Si[O—N═C(CH₃)CH₂CH₃]₄, and CH₂═CHSi[O—N═C(CH₃)CH₂CH₃]₃; organoacetamidosilanes such as CH₃Si[NHC(═O)CH₃]₃ and C₆H₅Si[NHC(═O)CH₃]₃; amino silanes such as CH₃Si[NH(s-C₄H₉)]₃ and CH₃Si(NHC₆H₁₁)₃; and organoaminooxysilanes.

The cross-linking agent can be a single silane or a mixture of two or more different silanes, each as described above. Also, methods of preparing tri- and tetra-functional silanes are well known in the art; many of these silanes are commercially available.

When present, the concentration of the cross-linking agent in the silicone composition is sufficient to cure (cross-link) the silicone resin. The exact amount of the cross-linking agent depends on the desired extent of cure, which generally increases as the ratio of the number of moles of silicon-bonded hydrolysable groups in the cross-linking agent to the number of moles of silicon-bonded hydrogen atoms, hydroxy groups, or hydrolysable groups in the silicone resin increases. Typically, the concentration of the cross-linking agent is sufficient to provide from 0.2 to 4 moles of silicon-bonded hydrolysable groups per mole of silicon-bonded hydrogen atoms, hydroxy groups, or hydrolysable groups in the silicone resin. The optimum amount of the cross-linking agent can be readily determined by routine experimentation.

As stated above, the condensation-curable silicone composition can further comprise at least one condensation catalyst. The condensation catalyst can be any condensation catalyst typically used to promote condensation of silicon-bonded hydroxy (silanol) groups to form Si—O—Si linkages. Examples of condensation catalysts include, but are not limited to, amines; and complexes of lead, tin, zinc, and iron with carboxylic acids. In particular, the condensation catalyst can be selected from tin(II) and tin(IV) compounds such as tin dilaurate, tin dioctoate, and tetrabutyl tin; and titanium compounds such as titanium tetrabutoxide.

When present, the concentration of the condensation catalyst is typically from 0.1 to 10% (w/w), alternatively from 0.5 to 5% (w/w), alternatively from 1 to 3% (w/w), based on the total weight of the silicone resin.

The radiation-curable silicone composition typically comprises a silicone resin having an average of at least two silicon-bonded radiation-sensitive groups per molecule and, optionally, a photoinitiator.

According to one embodiment, the radiation-curable silicone composition comprises a cured product of a silicone resin having the formula (R⁷R⁸₂SiO_{1/2})_{w} (R⁸₂SiO_{2/2})ₓ(R⁸SiO_{3/2})_{y}(SiO_{4/2})_{z} (IV), wherein each R⁷ is independently C₁ to C₁₀ hydrocarbyl, C₁ to C₁₀ halogen-substituted hydrocarbyl, or —OR⁶, wherein R⁶ is C₁ to C₈ hydrocarbyl or C₁ to C₈ halogen-substituted hydrocarbyl, each R⁵ is independently R¹, —H, or a radiation-sensitive group, w is from 0 to 0.95, x is from 0 to 0.95, y is from 0 to 1, z is from 0 to 0.9, y+z is from 0.1 to 1, and w+x+y+z=1, provided the silicone resin has an average of at least two silicon-bonded radiation-sensitive groups per molecule. In the formula (IV), R⁶, w, x, y, z, and y+z are as described and exemplified above. Also, the hydrocarbyl and halogen-substituted hydrocarbyl groups represented by R⁷ are as described and exemplified above for R⁴.

Examples of radiation-sensitive groups represented by R⁸ include, but are not limited to, acryloyloxyalkyl, substituted acryloyloxyalkyl, an alkenyl ether group, alkenyl, and an epoxy-substituted organic group. As used herein, the term “radiation-sensitive group” means the group forms a reactive species, for example a free radical or cation, in the presence of a free radical or cationic photoinitiator when exposed to radiation having a wavelength of from 150 to 800 nm.

Examples of acryloyloxyalkyl groups represented by R⁸ include, but are not limited to, acryloyloxymethyl, 2-acryloyloxyethyl, 3-acryloyloxyypropyl, and 4-acryloyloxybutyl.

Examples of substituted acryloyloxyalkyl groups represented by R⁸ include, but are not limited to, methacryloyloxymethyl, 2-methacryloyloxyethyl, and 3-methacryloyloxylpropyl.

Examples of alkenyl ether groups represented by R⁸ include, but are not limited to, a vinyl ether group having the formula and —O—R⁹—O—CH═CH₂, wherein R⁹ is C₁ to C₁₀ hydrocarbylene or C₁ to C₁₀ halogen-substituted hydrocarbylene.

The hydrocarbylene groups represented by R⁹ typically have from 1 to 10 carbon atoms, alternatively from 1 to 6 carbon atoms, alternatively from 1 to 4 carbon atoms. Examples of hydrocarbylene groups include, but are not limited to, alkylene such as methylene, ethylene, propane-1,3-diyl, 2-methylpropane-1,3-diyl, butane-1,4-diyl, butane-1,3-diyl, pentane-1,5,-diyl, pentane-1,4-diyl, hexane-1,6-diyl, octane-1,8-diyl, and decane-1,10-diyl; cycloalkylene such as cyclohexane-1,4-diyl; arylene such as phenylene. Examples of halogen-substituted hydrocarbylene groups include, but are not limited to, divalent hydrocarbon groups wherein one or more hydrogen atoms have been replaced by halogen, such as fluorine, chlorine, and bromine, such as —CH₂CH₂CF₂CF₂CH₂CH₂—.

Examples of alkenyl groups represented by R⁸ include, but are not limited to, vinyl, allyl, propenyl, butenyl, and hexenyl.

As used herein, the term “epoxy-substituted organic group” refers to a monovalent organic group in which an oxygen atom, the epoxy substituent, is directly attached to two adjacent carbon atoms of a carbon chain or ring system. Examples of epoxy-substituted organic groups represented by R⁸ include, but are not limited to, 2,3-epoxypropyl, 3,4-epoxybutyl, 4,5-epoxypentyl, 2-glycidoxyethyl, 3-glycidoxypropyl, 4-glycidoxybutyl, 2-(3,4-epoxycylohexyl)ethyl, 3-(3,4-epoxycylohexyl)propyl, 2-(3,4-epoxy-3-methylcylohexyl)-2-methylethyl, 2-(2,3-epoxycylopentyl)ethyl, and 3-(2,3 epoxycylopentyl)propyl. The silicone resin typically contains an average of at least two silicon-bonded radiation-sensitive groups per molecule. Generally, at least 50 mol %, alternatively at least 65 mol %, alternatively at least 80 mol % of the groups R⁸ in the silicone resin are radiation-sensitive groups. The term “mol % of the groups R⁸ in the silicone resin are radiation-sensitive groups” is defined as the ratio of the number of moles of silicon-bonded radiation-sensitive groups in the silicone resin to the total number of moles of the groups R⁸ in the resin, multiplied by 100.

Examples of silicone resins having the formula (IV) include, but are not limited to, resins having the following formulae:

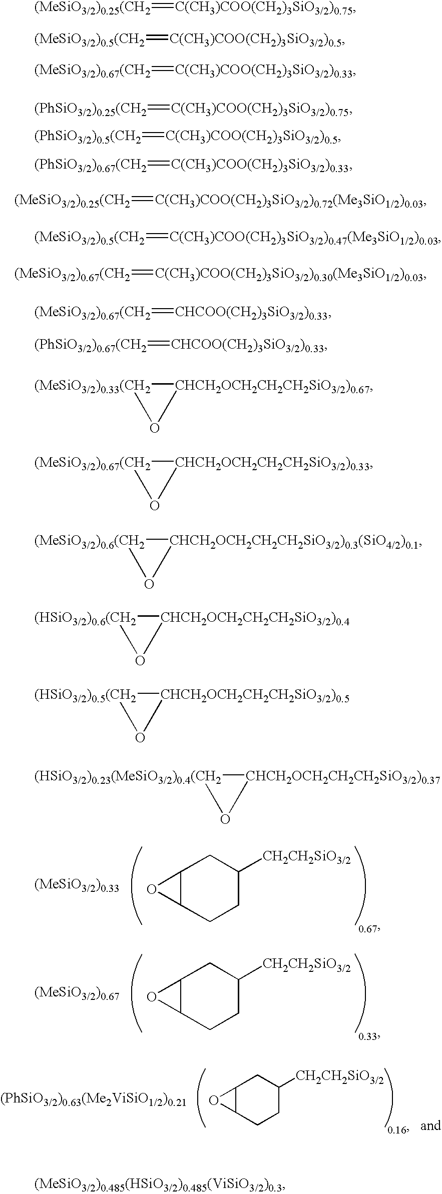

where Me is methyl, Ph is phenyl, Vi is vinyl, and the numerical subscripts outside the parenthesis denote mole fractions. Also, in the preceding formulae, the sequence of units is unspecified.

Methods of preparing silicone resins having silicon-bonded radiation-sensitive groups are known in the art. For example, silicone resins containing silicon-bonded acryloyloxyalkyl or substituted acryloyloxyalkyl groups can be prepared by co-hydrolyzing an acryloyloxyalkyl- or substituted-acryloyloxyalkylalkoxysilane and an alkoxysilane in the presence of an acidic or basic catalyst, as exemplified in U.S. Pat. No. 5,738,976 and U.S. Pat. No. 5,959,038. Alternatively, such resins can be produced by co-hydrolyzing an acryloyloxyalkyl- or substituted-acryloyloxayalkylchlorosilane and at least one chlorosilane, as taught in U.S. Pat. No. 4,568,566.

Silicone reins containing silicon-bonded alkenyl ether groups can be prepared by reacting an alkoxysilane with water in the presence of an acidic condensation catalyst and subsequently treating the reaction mixture with a hydroxy-substituted vinyl ether and a transesterification catalyst, as described in U.S. Pat. No. 5,861,467. In brief this method comprises the steps of (I) reacting (a) a silane having the formula RₓSi(OR¹)₄₋ₓ, (b) water, and (c) an acidic condensation catalyst; (II) removing alcohol from the mixture of step (I), (III) neutralizing the mixture of step (II), (IV) adding a vinyl ether compound having the formula HO—R²—O—CH═CH₂, (V) adding a transesterification catalyst to the mixture of step (IV); and (VI) removing volatiles from the mixture of step (V); wherein R is a monovalent hydrocarbon or halohydrocarbon radical having from 1 to 20 carbon atoms, R¹ is a monovalent alkyl radical having from 1 to 8 carbon atoms, R² is a divalent hydrocarbon or halohydrocarbon radical having from 1 to 20 carbon atoms, and x has a value of from 0 to 3, with the proviso that the molar ratio of water to alkoxy radicals is less than 0.5. Alternatively, silicone resins containing alkenyl ether groups can be prepared by reacting an alkoxysilane, water, and a hydroxy-substituted vinyl ether compound in the presence of a non-acidic condensation catalyst, and then treating the reaction mixture with a transesterification catalyst, as described in U.S. Pat. No. 5,824,761. Briefly, this method comprises (I) reacting (a) a silane having the formula RₓSi(OR¹)₄₋ₓ, (b) water, (c) a non-acidic condensation catalyst selected from amine carboxylates, heavy metal carboxylates, isocyanates, silanolates, phenoxides, mercaptides, CaO, BaO, LiOH, BuLi, amines, and ammonium hydroxides, and (d) a vinyl ether compound having the formula HO—R²—O—CH═CH₂; (II) removing alcohol from the mixture of (I); (III) neutralizing the mixture of (II); (IV) adding a transesterification catalyst to the mixture of (III); and (V) removing volatiles from the mixture of (IV); wherein R is a monovalent hydrocarbon or halohydrocarbon radical having from 1 to 20 carbon atoms, R¹ is a monovalent alkyl radical having from 1 to 8 carbon atoms, R² is a divalent hydrocarbon or halohydrocarbon radical having from 1 to 20 carbon atoms, and x has a value of from 0 to 3, with the proviso that the molar ratio of water to alkoxy radicals is less than 0.5.

Silicone resins containing silicon-bonded alkenyl groups can be prepared as describe above for the silicone resin having the formula (I).

Silicone resins containing silicon-bonded epoxy-substituted organic groups can be prepared by cohydrolyzing an epoxy-functional alkoxysilane and an alkoxysilane in the presence of an organotitanate catalyst, as described in U.S. Pat. No. 5,468,826. Alternatively, silicone resins containing silicon-bonded epoxy-substituted organic groups can be prepared by reacting a silicone resin containing silicon-bonded hydrogen atoms with an epoxy-functional alkene in the presence of a hydrosilylation catalyst, as described in U.S. Pat. Nos. 6,831,145; 5,310,843; 5,530,075; 5,283,309; 5,468,827; 5,486,588; and 5,358,983.

The radiation-curable silicone composition can comprise additional ingredients, provided the ingredient does not prevent the silicone resin from curing to form the first interfacial coating, described above, of the electronic package. Examples of additional ingredients include, but are not limited to, adhesion promoters; dyes; pigments; anti-oxidants; heat stabilizers; flame retardants; flow control additives; fillers, including extending and reinforcing fillers; organic solvents; cross-linking agents; and photoinitiators.

For example, the radiation-curable silicone composition can further comprise at least one photoinitiator. The photoinitiator can be a cationic or free radical photoinitiator, depending on the nature of the radiation-sensitive groups in the silicone resin. For example, when the resin contains alkenyl ether or epoxy-substituted organic groups, the silicone composition can further comprise at least one cationic photoinitiator. The cationic photoinitiator can be any cationic photoinitiator capable of initiating cure (cross-linking) of the silicone resin upon exposure to radiation having a wavelength of from 150 to 800 nm. Examples of cationic photoinitiators include, but are not limited to, onium salts, diaryliodonium salts of sulfonic acids, triarylsulfonium salts of sulfonic acids, diaryliodonium salts of boronic acids, and triarylsulfonium salts of boronic acids. Suitable onium salts include salts having a formula selected from R¹⁰₂ I+MX_{z}⁻, R¹⁰₃S⁺MX_{z}⁻, R¹⁰₃Se⁺ MX_{z}⁻, R¹⁰₄P⁺MX_{z}⁻, and R¹⁰₄N⁺MX_{z}⁻, wherein each R¹⁰ is independently hydrocarbyl or substituted hydrocarbyl having from 1 to 30 carbon atoms; M is an element selected from transition metals, rare earth metals, lanthanide metals, metalloids, phosphorus, and sulfur; X is a halo (e.g., chloro, bromo, iodo), and z has a value such that the product z (charge on X+oxidation number of M)=−1. Examples of substituents on the hydrocarbyl group include, but are not limited to, C₁ to C₈ alkoxy, C₁ to C₁₆ alkyl, nitro, chloro, bromo, cyano, carboxyl, mercapto, and heterocyclic aromatic groups, such as pyridyl, thiophenyl, and pyranyl. Examples of metals represented by M include, but are not limited to, transition metals, such as Fe, Ti, Zr, Sc, V, Cr, and Mn; lanthanide metals, such as Pr, and Nd; other metals, such as Cs, Sb, Sn, Bi, Al, Ga, and In; metalloids, such as B, and As; and P. The formula MX_{z}⁻ represents a non-basic, non-nucleophilic anion. Examples of anions having the formula MX_{z}⁻ include, but are not limited to, BF₄⁻, PF₆⁻, AsF₆⁻, SbF₆⁼, SbCl₆⁻, and SnCl₆⁻.

Examples of onium salts include, but are not limited to, bis-diaryliodonium salts, such as bis(dodecyl phenyl)iodonium hexafluoroarsenate, bis(dodecylphenyl)iodonium hexafluoroantimonate, and dialkylphenyliodonium hexafluoroantimonate.

Examples of diaryliodonium salts of sulfonic acids include, but are not limited to, diaryliodonium salts of perfluoroalkylsulfonic acids, such as diaryliodonium salts of perfluorobutanesulfonic acid, diaryliodonium salts of perfluoroethanesulfonic acid, diaryliodonium salts of perfluorooctanesulfonic acid, and diaryliodonium salts of trifluoromethanesulfonic acid; and diaryliodonium salts of aryl sulfonic acids, such as diaryliodonium salts of para-toluenesulfonic acid, diaryliodonium salts of dodecylbenzenesulfonic acid, diaryliodonium salts of benzenesulfonic acid, and diaryliodonium salts of 3-nitrobenzenesulfonic acid.

Examples of triarylsulfonium salts of sulfonic acids include, but are not limited to, triarylsulfonium salts of perfluoroalkylsulfonic acids, such as triarylsulfonium salts of perfluorobutanesulfonic acid, triarylsulfonium salts of perfluoroethanesulfonic acid, triarylsulfonium salts of perfluorooctanesulfonic acid, and triarylsulfonium salts of trifluoromethanesulfonic acid; and triarylsulfonium salts of aryl sulfonic acids, such as triarylsulfonium salts of para-toluenesulfonic acid, triarylsulfonium salts of dodecylbenzenesulfonic acid, triarylsulfonium salts of benzenesulfonic acid, and triarylsulfonium salts of 3-nitrobenzenesulfonic acid.

Examples of diaryliodonium salts of boronic acids include, but are not limited to, diaryliodonium salts of perhaloarylboronic acids. Examples of triarylsulfonium salts of boronic acids include, but are not limited to, triarylsulfonium salts of perhaloarylboronic acid. Diaryliodonium salts of boronic acids and triarylsulfonium salts of boronic acids are well known in the art, as exemplified in European Patent Application No. EP 0562922. The cationic photoinitiator can be a single cationic photoinitiator or a mixture comprising two or more different cationic photoinitiators, each as described above. The concentration of the cationic photoinitiator is typically from 0.01 to 20% (w/w), alternatively from 0.1 to 20% (w/w), alternatively from 0.1 to 5%, based on the weight of the silicone resin.

When the silicone resin contains acryoyloxyalkyl, substituted acryloyloxyalkyl, or alkenyl groups, the silicone composition can further comprise at least one free radical photoinitiator. The free radical photoinitiator can be any free radical photoinitiator capable of initiating cure (cross-linking) of the silicone resin upon exposure to radiation having a wavelength of from 150 to 800 nm.

Examples of free radical photoinitiators include, but are not limited to, benzophenone; 4,4′-bis(dimethylamino)benzophenone; halogenated benzophenones; acetophenone; α-hydroxyacetophenone; chloro acetophenones, such as dichloroacetophenones and trichloroacetophenones; dialkoxyacetophenones, such as 2,2-diethoxyacetophenone; α-hydroxyalkylphenones, such as 2-hydroxy-2-methyl-1-phenyl-1-propanone and 1-hydroxycyclohexyl phenyl ketone; α-aminoalkylphenones, such as 2-methyl-4′-(methylthio)-2-morpholiniopropiophenone; benzoin; benzoin ethers, such as benzoin methyl ether, benzoin ethyl ether, and benzoin isobutyl ether; benzil ketals, such as 2,2-dimethoxy-2-phenylacetophenone; acylphosphinoxides, such as diphenyl(2,4,6-trimethylbenzoyl)phosphine oxide; xanthone derivatives; thioxanthone derivatives; fluorenone derivatives; methyl phenyl glyoxylate; acetonaphthone; anthraquninone derivatives; sulfonyl chlorides of aromatic compounds; and O-acyl α-oximinoketones, such as 1-phenyl-1,2-propanedione-2-(O-ethoxycarbonyl)oxime. The free radical photoinitiator can also be a polysilane, such as the phenylmethylpolysilanes defined by West in U.S. Pat. No. 4,260,780, which is hereby incorporated by reference; the aminated methylpolysilanes defined by Baney et al. in U.S. Pat. No. 4,314,956, which is hereby incorporated by reference; the methylpolysilanes of Peterson et al. in U.S. Pat. No. 4,276,424, which is hereby incorporated by reference; and the polysilastyrene defined by West et al. in U.S. Pat. No. 4,324,901, which is hereby incorporated by reference.

The free radical photoinitiator can be a single free radical photoinitiator or a mixture comprising two or more different free radical photoinitiators. The concentration of the free radical photoinitiator is typically from 0.1 to 20% (w/w), alternatively from 1 to 10% (w/w), based on the weight of the silicone resin.

The peroxide-curable silicone composition typically comprises a silicone resin having silicon-bonded unsaturated groups and an organic peroxide.

According to one embodiment, the peroxide-curable silicone composition comprises a silicone resin having the formula (R¹R¹¹₂SiO_{1/2})_{w}(R¹¹₂SiO_{2/2})ₓ(R¹¹SiO_{3/2})_{y}(SiO_{4/2})_{z} (V), wherein each R¹ is independently C₁ to C₁₀ hydrocarbyl or C₁ to C₁₀ halogen-substituted hydrocarbyl, both free of aliphatic unsaturation; each R¹¹ is independently R¹, alkenyl, alkynyl, acryloxyalkyl, or substituted acryloxyalkyl; w is from 0 to 0.95, x is from 0 to 0.95, y is from 0 to 1, z is from 0 to 0.9, y+z is from 0.1 to 1, and w+x+y+z=1; and an organic peroxide. In the formula (V), R¹, w, x, y, z, and y+z are as described and exemplified above for the silicone resin having the formula (I).

The alkenyl groups represented by R¹¹, which may be the same or different, typically have from 2 to about 10 carbon atoms, alternatively from 2 to 6 carbon atoms, and are exemplified by, but not limited to, vinyl, allyl, butenyl, hexenyl, and octenyl.

The alkynyl groups represented by R¹¹, which may be the same or different, typically have from 2 to about 10 carbon atoms, alternatively from 2 to 6 carbon atoms, and are exemplified by, but not limited to, ethynyl, propynyl, butynyl, hexynyl, and octynyl.

In one embodiment of the silicone resin, the resin contains an average of at least one alkenyl group or alkynyl group per molecule.

The silicone resin typically contains less than 10% (w/w), alternatively less than 5% (w/w), alternatively less than 2% (w/w), of silicon-bonded hydroxy groups, as determined by ²⁹Si NMR.

Examples of silicone resins having the formula (V) include, but are not limited to, resins having the following formulae:

(Vi₂MeSiO_{1/2})_{0.25}(PhSiO_{3/2})_{0.75}, (ViMe₂SiO_{1/2})_{0.25}(PhSiO_{3/2})_{0.75}, (ViMe₂SiO_{1/2})_{0.25}(MeSiO_{3/2})_{0.25}(PhSiO_{3/2})_{0.50}, (ViMe₂SiO_{1/2})_{0.15}(PhSiO_{3/2})_{0.75}(SiO_{4/2})_{0.1}, and (Vi₂MeSiO_{1/2})_{0.15}(ViMe₂SiO_{1/2})_{0.1}(PhSiO_{3/2})_{0.75}, where Me is methyl, Vi is vinyl, Ph is phenyl, and the numerical subscripts outside the parenthesis denote mole fractions. Also, in the preceding formulae, the sequence of units is unspecified.

The silicone resin can be a single silicone resin or a mixture comprising two or more different silicone resins, each as described above.

Methods of preparing silicone resins having silicon-bonded alkenyl groups or silicon-bonded alkynyl groups are well known in the art; many of these resins are commercially available. These resins are typically prepared by cohydrolyzing the appropriate mixture of chlorosilane precursors in an organic solvent, such as toluene. For example, a silicone resin consisting essentially of R¹R¹¹₂SiO_{1/2} units and R¹¹SiO_{3/2} units can be prepared by cohydrolyzing a compound having the formula R¹R¹¹₂SiCl and a compound having the formula R¹¹SiCl₃ in toluene, where R¹ and R¹¹ are as defined and exemplified above. The aqueous hydrochloric acid and silicone hydrolyzate are separated and the hydrolyzate is washed with water to remove residual acid and heated in the presence of a mild condensation catalyst to “body” the resin to the requisite viscosity. If desired, the resin can be further treated with a condensation catalyst in an organic solvent to reduce the content of silicon-bonded hydroxy groups. Alternatively, silanes containing hydrolysable groups other than chloro, such —Br, —I, —OCH₃, —OC(O)CH₃, —N(CH₃)₂, —NHCOCH₃, and —SCH₃, can be utilized as starting materials in the cohydrolysis reaction. The properties of the resin products depend on the types of silanes, the mole ratio of silanes, the degree of condensation, and the processing conditions.

Examples of organic peroxides include, diaroyl peroxides such as dibenzoyl peroxide, di-p-chlorobenzoyl peroxide, and bis-2,4-dichlorobenzoyl peroxide; dialkyl peroxides such as di-t-butyl peroxide and 2,5-dimethyl-2,5-di-(t-butylperoxy)hexane; diaralkyl peroxides such as dicumyl peroxide; alkyl aralkyl peroxides such as t-butyl cumyl peroxide and 1,4-bis(t-butylperoxyisopropyl)benzene; and alkyl aroyl peroxides such as t-butyl perbenzoate, t-butyl peracetate, and t-butyl peroctoate.

The organic peroxide can be a single peroxide or a mixture comprising two or more different organic peroxides. The concentration of the organic peroxide is typically from 0.1 to 5% (w/w), alternatively from 0.2 to 2% (w/w), based on the weight of the silicone resin.

The peroxide-curable silicone composition of the present invention can comprise additional ingredients, provided the ingredient does not prevent the silicone resin of the silicone composition from curing to form the first interfacial coating, described above, of the electronic package. Examples of additional ingredients include, but are not limited to, silicone rubbers; polyunsaturated compounds; free radical initiators; organic solvents; UV stabilizers; sensitizers; dyes; flame retardants; antioxidants; fillers, such as reinforcing fillers, extending fillers, and conductive fillers; and adhesion promoters.

In step (i) of the first method of forming the first interfacial coating, the curable silicone composition can be applied on the first inorganic barrier coating in a region over the electronic device using conventional printing methods, such as ink jet printing, screen printing, stencil printing, flexography, lithography, gravure printing, soft lithography, xerography, imprinting (embossing), microdispensing, friction transfer printing, laser transfer printing, and thermal transfer printing. The particular method selected will depend on several factors, including the rheology of the silicone composition, the desired thickness of the coating, application temperature, and desired resolution. The amount of silicone composition is sufficient to form a cured silicone resin film having a thickness of from 0.06 to 30 μm in step (ii) of the method, described below.

In step (ii) of the first method of preparing the first interfacial coating, the silicone resin of the film is cured. The silicone resin of the film can be cured by exposing the film to ambient temperature, elevated temperature, moisture, or radiation, depending on the type of curable silicone composition applied on the first inorganic barrier coating.

When the silicone composition applied on the first inorganic barrier coating is a hydrosilylation-curable silicone composition, the silicone resin can be cured by heating the resin to a temperature of from room temperature (˜23±2° C.) to 250° C., alternatively from room temperature to 200° C., alternatively from room temperature to 150° C., at atmospheric pressure. The resin is heated for a length of time sufficient to cure (cross-link) the silicone resin. For example, the resin is typically heated at a temperature of from 150 to 200° C. for a time of from 0.1 to 3 h.

When the silicone composition applied on the first inorganic barrier coating is a condensation-curable silicone composition, the conditions for curing the silicone resin depend on the nature of the silicon-bonded groups in the resin. For example, when the silicone resin contains silicon-bonded hydroxy groups, the silicone resin can be cured (i.e., cross-linked) by heating the film. For example, the silicone resin can typically be cured by heating the film at a temperature of from 50 to 250° C., for a period of from 1 to 50 h. When the condensation-curable silicone composition comprises a condensation catalyst, the silicone resin can typically be cured at a lower temperature, e.g., from room temperature (˜23±2° C.) to 200° C.

When the silicone resin contains silicon-bonded hydrogen atoms, the silicone resin can be cured by exposing the film to moisture or oxygen at a temperature of from 100 to 450° C. for a period of from 0.1 to 20 h. When the condensation-curable silicone composition contains a condensation catalyst, the silicone resin can typically be cured at a lower temperature, e.g., from room temperature (˜23±2° C.) to 400° C.

Further, when the silicone resin contains silicon-bonded hydrolysable groups, the silicone resin can be cured by exposing the film to moisture at a temperature of from room temperature (˜23±2° C.) to 250° C., alternatively from 100 to 200° C., for a period of from 1 to 100 h. For example, the silicone resin can typically be cured by exposing the film to a relative humidity of 30% at a temperature of from about room temperature (˜23±2° C.) to 150° C., for a period of from 0.5 to 72 h. Cure can be accelerated by application of heat, exposure to high humidity, and/or addition of a condensation catalyst to the composition.

When the silicone composition applied on the first inorganic barrier coating is a radiation-curable silicone composition, the silicone resin can be cured by exposing the film to an electron beam. Typically, the accelerating voltage is from about 0.1 to 100 keV, the vacuum is from about 10 to 10⁻³ Pa, the electron current is from about 0.0001 to 1 ampere, and the power varies from about 0.1 watt to 1 kilowatt. The dose is typically from about 100 microcoulomb/cm² to 100 coulomb/cm², alternatively from about 1 to 10 coulombs/cm². Depending on the voltage, the time of exposure is typically from about 10 seconds to 1 hour.

Also, when the silicone composition further comprises a cationic or free radical photoinitiator, described above, the silicone resin can be cured by exposing the film to radiation having a wavelength of from 150 to 800 nm, alternatively from 200 to 400 nm, at a dosage sufficient to cure (cross-link) the silicone resin. The light source is typically a medium pressure mercury-arc lamp. The dose of radiation is typically from 30 to 1,000 mJ/cm², alternatively from 50 to 500 mJ/cm². Moreover, the film can be externally heated during or after exposure to radiation to enhance the rate and/or extent of cure.

When the silicone composition applied on the first inorganic barrier coating is a peroxide-curable silicone composition, the silicone resin can be cured by heating the film at a temperature of from room temperature (˜23±2° C.) to 180° C., for a period of from 0.05 to 1 h.

When the first interfacial coating is a cured product of a silicone resin having radiation-sensitive groups, the first interfacial coating can be formed by a first photolithography method comprising (i) applying a radiation-curable silicone composition on the first inorganic barrier coating to form a film, wherein the silicone composition comprises a silicone resin having an average of at least two silicon-bonded radiation-sensitive groups per molecule; (ii) exposing the film to radiation having a wavelength of from 150 to 800 nm in a region over the electronic device to produce a partially exposed film having at least one exposed region and at least one non-exposed region; and (iii) removing the non-exposed region of the heated film with a developing solvent to form a patterned film.

In step (i) of the first photolithography method, the radiation-curable silicone composition can be applied on the first inorganic barrier coating using conventional printing methods, such as ink jet printing, screen printing, stencil printing, flexography, lithography, gravure printing, soft lithography, xerography, imprinting (embossing), microdispensing, friction transfer printing, laser transfer printing, and thermal transfer printing. The particular method selected will depend on several factors, including the rheology of the silicone composition, the desired thickness of the coating, application temperature, and desired resolution. The amount of silicone composition is sufficient to form a cured silicone resin film having a thickness of from 0.06 to 30 μm in the step (iii) of the method, described below.

When the radiation-curable silicone composition comprises a solvent, the method can further comprise removing at least a portion of the solvent from the silicone film. The solvent can be removed by heating the silicone film at a temperature of from 30 to 150° C. for 1 to 5 min, alternatively from 60 to 120° C. for 1 to 5 min.

In step (ii) of the first photolithography method, the film is exposed to radiation having a wavelength of from 150 to 800 nm, alternatively from 250 to 450 nm, in a region over the electronic device to produce a partially exposed film having at least one exposed region and at least one non-exposed region. The light source typically used is a medium pressure mercury-arc lamp. The dose of radiation is typically from 0.1 to 5,000 mJ/cm², alternatively from 250 to 1,300 mJ/cm². The region of the film over the electronic device is exposed to radiation through a photomask.

In step (iii) of the first photolithography method, the non-exposed region of the partially exposed film is removed with a developing solvent to form a patterned film. The developing solvent is an organic solvent in which the non-exposed region of the partially exposed film is at least partially soluble and the exposed region is essentially insoluble. The developing solvent typically has from 3 to 20 carbon atoms. Examples of developing solvents include ketones, such as methyl isobutyl ketone and methyl pentyl ketone; ethers, such as n-butyl ether and polyethylene glycol monomethylether; esters, such as ethyl acetate and γ-butyrolactone; aliphatic hydrocarbons, such as nonane, decalin, and dodecane; and aromatic hydrocarbons, such as mesitylene, xylene, and toluene. The developing solvent can be applied by any conventional method, including spraying, immersion, and pooling. Preferably, the developing solvent is applied by forming a pool of the solvent on a stationary substrate and then spin-drying the substrate. The developing solvent is typically used at a temperature of from room temperature to 100° C. However, the specific temperature will depend on the chemical properties of the solvent, the boiling point of the solvent, the desired rate of pattern formation, and the requisite resolution of the photopatterning process.

Alternatively, when the first interfacial coating is a cured product of a silicone resin having radiation-sensitive groups, the first interfacial coating can be formed by a second photolithography method comprising (i) applying a radiation-curable silicone composition on the first inorganic barrier coating to form a film, wherein the silicone composition comprises a silicone resin having an average of at least two silicon-bonded radiation-sensitive groups per molecule; (ii) exposing the film to radiation having a wavelength of from 150 to 800 nm in a region over the electronic device to produce a partially exposed film having at least one exposed region and at least one non-exposed region; (iii) heating the partially exposed film for an amount of time such that the exposed region is substantially insoluble in a developing solvent and the non-exposed region is soluble in the developing solvent; and (iv) removing the non-exposed region of the heated film with the developing solvent to form a patterned film.

Steps (i) and (ii) of the second photolithography method are identical to steps (i) and (ii) of the first photolithography method, described above.

In step (iii) of the second photolithography method, the partially exposed film is heated for an amount of time such that the region exposed to radiation (“exposed region”) is substantially insoluble in a developing solvent. The region that was not previously exposed to radiation (“non-exposed region”) is soluble in the developing solvent. The term “substantially insoluble” means that the exposed region of the silicone film is not removed by dissolution in the developing solvent to the extent that the underlying surface of the substrate is exposed. The term “soluble” means that the unexposed region of the silicone film is removed by dissolution in the developing solvent, exposing the underlying surface of the substrate. The partially exposed film is typically heated at a temperature of from 50 to 250° C. for 0.1 to 10 min, alternatively from 100 to 200° C. for 1 to 5 min, alternatively from 135 to 165° C. for 2 to 4 min. The partially exposed film can be heated using conventional equipment such as a hot plate or oven.

In step (iv) of the second photolithography method, the non-exposed region of the heated film is removed with the developing solvent to form a patterned film. The non-exposed region of the heated film can be removed as described above in step (iii) of the first photolithography method.

The second or third photolithography methods of forming the first interfacial coating can further comprise heating the patterned film. The patterned film is typically heated for an amount of time sufficient to achieve maximum crosslink density in the silicone without oxidation or decomposition. The patterned film is typically heated at a temperature of from 50 to 300° C. for 1 to 300 min, alternatively from 75 to 275° C. for 10 to 120 min, alternatively from 200 to 250° C. for 20 to 60 min.

According to the method of preparing the electronic package, a second inorganic barrier coating is formed on the first interfacial coating and any portion of the first inorganic barrier coating not covered by the first interfacial coating; provided no coating is formed on at least a portion of each electrical contact. The second inorganic barrier coating and methods of forming it are as described and exemplified above for the first inorganic barrier coating.

The method of preparing the electronic package can further comprise forming at least two alternating interfacial and inorganic barrier coatings on the second inorganic barrier coating, wherein each alternating interfacial coating comprises a cured product of a silicone resin.

The composite inorganic barrier and interfacial coatings of the electronic package have a low water vapor transmission rate, typically from 1×10⁻⁷ to 3 g/m²/day. Also, the coatings have low permeability to oxygen and metal ions, such as copper and aluminum. Further, the coatings can be transparent or nontransparent to light in the visible region of the electromagnetic spectrum. Still further, the coatings have high resistance to cracking and low compressive stress.

The method of preparing the electronic package of the present invention can be carried out using conventional equipment and techniques, and readily available silicone compositions. For example inorganic barrier coatings can be deposited using chemical vapor deposition techniques and physical vapor deposition techniques. Moreover, interfacial coatings can be formed using conventional methods of applying and curing silicone compositions. Also, the methods of the present invention are scaleable to high throughput manufacturing processes.

The electronic package of the present invention is useful for fabricating a wide range of consumer electronic products, including light-emitting arrays or displays, calculators, telephones, televisions, and mainframe and personal computers.

### EXAMPLES

The following examples are presented to better illustrate methods of forming the interfacial coating of the present invention, but are not to be considered as limiting the invention, which is delineated in the appended claims. Unless otherwise noted, all parts and percentages reported in the examples are by weight. The following methods and materials were employed in the examples:

### NMR Spectra

Nuclear magnetic resonance spectra (²⁹Si NMR and ¹³C NMR) of silicone resins were obtained using a Varian Mercury 400 MHz NMR spectrometer. The resin (0.5-1.0 g) was dissolved in 2.5-3 mL of chloroform-d in a 0.5 oz glass vial The solution was transferred to a Teflon NMR tube and 3-4 mL of a solution of Cr(acac)₃ in chloroform-d (0.04 M) was added to the tube.

### Molecular Weight

Weight-average molecular weight (M_{w}) of silicone resins having radiation-sensitive groups were determined by gel permeation chromatography (GPC) using a PLgel (Polymer Laboratories, Inc.) 5-μm column at 35° C., a THF mobile phase at 1 mL/min, and a refractive index detector. Polystyrene standards were used for a calibration curve (3^{rd} order). The M_{w} of hydrogensilsesquioxane resins were determined in the same manner, only the mobile phase was toluene.

### Reagents

Dow Corning® 9820 Photocatalyst: a mixture containing 1% of 3-iodotoluene, 5% of 2-isopropylthioxanthone, 41% of ((3-Methylphenyl) ((C12-13 branched) phenyl) iodonium hexafluoroantimon, and 50% of 1-decanol.

Irgacure® 819 Photoinitiator: bis(2,4,6-trimethylbenzoyl)phenylphosphine oxide, sold by Ciba Specialty Chemicals.

### Example 1

Toluene (2400 g), 2.40 mol of 3-glycidoxypropyltrimethoxysilane, 4.80 mol of methyltrimethoxysilane, 28.8 mol of water, 2.4 mL of tetramethylammonium hydroxide solution (25% aqueous), and 2400 g of methanol were combined in a flask. The mixture was stirred and heated at reflux for 2 h, during which time 6950 g of solvent, primarily methanol, was removed by distillation using a Dean-Stark trap. During the distillation toluene was added to the mixture to maintain a constant resin concentration. The temperature of the mixture was slowly increased to about 110° C. during about 1 h. The mixture was then allowed to cool to room temperature. Acetic acid (3.4 mL) was then added drop-wise to the stirred mixture over a period 1 h. The mixture was washed with 1,600 mL of deionized water (ten times) and then filtered. Toluene was removed under reduced pressure at 40° C. using a rotary evaporator. The residue was placed under vacuum (1 Pa) at room temperature for 3 h to give a silicone resin having the formula:

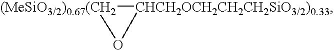

as determined by ²⁹Si NMR and ¹³C NMR, and weight-average molecular weight of 1900.

### Example 2

Toluene (80 g), 0.20 mol of 3-methacryloxypropyltrimethoxysilane, 0.40 mol of phenyltrimethoxysilane, 2.40 mol of water, 1 g of a 50% (w/w) aqueous solution of cesium hydroxide, 200 g of methanol, and 40 mg of 2,6-di-tert-butyl-4-methylphenol were combined in a flask. The solution was heated at reflux for 1 h, during which time 250 g of solvent, primarily methanol, was removed by distillation using a Dean-Stark trap. During the distillation toluene was added to the mixture to maintain a constant resin concentration. The temperature of the mixture was slowly increased to about 105° C. during about 1 h. The mixture was then allowed to cool to room temperature. Toluene was removed under reduced pressure at 40° C. using a rotary evaporator. The residue was placed under vacuum (1 Pa) at room temperature for 3 h to give a silicone resin having the formula:

(PhSiO_{3/2})_{0.67}(CH₂═C(CH₃)C(═O)OCH₂CH₂CH₂SiO_{3/2})_{0.33},

as determined by ²⁹Si NMR and ¹³C NMR, and a weight-average molecular weight of 8294.

### Example 3

A solution consisting of 5% Dow Corning® 9820 Photocatalyst in the silicone resin of Example 1 was passed through a 0.2 μm filter. A piece of felt (1.5″×0.75″×0.25″) was cut from an all purpose eraser for use as an inking pad. The felt was placed inside a Petri dish and saturated with the resin solution. The resin was transferred from the felt pad to a silicon substrate using a positive image rubber stamp. The coating was exposed to ˜1 J/cm² of UV radiation at 450 W/in. using a Fusion UV Light System equipped with a mercury H-bulb (200-320 nm) to give a tack-free film.

### Example 4

A solution consisting of 30% of the silicone resin of Example 2 and 10% of Irgacure® 819 Photoinitiator in propylene glycol methyl ether acetate was passed through a 0.2 μm filter. A piece of felt (1.5″×0.75″×0.25″) was cut from an all purpose eraser for use as an inking pad. The felt was placed inside a Petri dish and saturated with the resin solution. The resin was transferred from the felt pad to a silicon substrate using a positive image rubber stamp. The coating was exposed to ˜1 J/cm² of UV radiation at 450 W/in. using a Fusion UV Light System equipped with a mercury H-bulb (200-320 nm) to give a tack-free film.

That which is claimed is:

1. An electronic package, comprising:
a substrate;
at least one electronic device having electrical contacts, the device positioned on or within the substrate;
a first inorganic barrier coating on the substrate and the electronic device;
a first interfacial coating on the first inorganic barrier coating in a region over the electronic device, wherein the first interfacial coating comprises a cured product of a silicone resin; and
a second inorganic barrier coating on the first interfacial coating and any portion of the first inorganic barrier coating not covered by the first interfacial coating; provided at least a portion of each electrical contact has no coating.

2. The electronic package according to claim 1, wherein the first inorganic barrier coating is a single layer coating comprising one layer of an inorganic material.

3. The electronic package according to claim 2, wherein the single layer coating has a thickness of from 0.03 to 3 μm.

4. The electronic package according to claim 1, wherein the first inorganic barrier coating is a multiple layer coating comprising two or more layers of at least two different inorganic materials.

5. The electronic package according to claim 4, wherein the multiple layer coating has a thickness of from 0.06 to 5 μm.

6. The electronic package according to claim 1, wherein the package further comprises at least two alternating interfacial and inorganic barrier coatings on the second inorganic barrier coating.

7. A method of preparing an electronic package, the method comprising:
forming a first inorganic barrier coating on a substrate and at least one electronic device having electrical contacts, the electronic device positioned on or within the substrate;
forming a first interfacial coating on the first inorganic barrier coating in a region over the electronic device, wherein the first interfacial coating comprises a cured product of a silicone resin; and
forming a second inorganic barrier coating on the first interfacial coating and any portion of the first inorganic barrier coating not covered by the first interfacial coating; provided no coating is formed on at least a portion of each electrical contact.

8. The method according to claim 7, wherein the first interfacial coating is formed by a method comprising (i) applying a curable silicone composition comprising a silicone resin on the first inorganic barrier coating in a region over the electronic device to form a film, and (ii) curing the silicone resin of the film.

9. The method according to claim 8, wherein the curable silicone composition is selected from a hydrosilylation-curable silicone compositions, condensation-curable silicone compositions, radiation-curable silicone compositions, and peroxide-curable silicone compositions.

10. The method according to claim 8, wherein the curable silicone composition is applied on the first inorganic barrier coating by printing.

11. The method according to claim 7, wherein the silicone resin has radiation-sensitive groups and wherein the first interfacial coating is formed by a photolithography method comprising (i) applying a radiation-curable silicone composition on the first inorganic barrier coating to form a film, wherein the silicone composition comprises a silicone resin having an average of at least two silicon-bonded radiation-sensitive groups per molecule; (ii) exposing the film to radiation having a wavelength of from 150 to 800 nm in a region over the electronic device to produce a partially exposed film having at least one exposed region and at least one non-exposed region; and (iii) removing the non-exposed region of the heated film with a developing solvent to form a patterned film.

12. The method according to claim 7, wherein the silicone resin has radiation-sensitive groups and wherein the first interfacial coating is formed by a photolithography method comprising (i) applying a radiation-curable silicone composition on the first inorganic barrier coating to form a film, wherein the silicone composition comprises a silicone resin having an average of at least two silicon-bonded radiation-sensitive groups per molecule; (ii) exposing the film to radiation having a wavelength of from 150 to 800 nm in a region over the electronic device to produce a partially exposed film having at least one exposed region and at least one non-exposed region; (iii) heating the partially exposed film for an amount of time such that the exposed region is substantially insoluble in a developing solvent and the non-exposed region is soluble in the developing solvent; and (iv) removing the non-exposed region of the heated film with the developing solvent to form a patterned film.
